(19) United States
(12) Patent Application Publication
(10) Pub. No.: US 2008/0290885 A1
(43) Pub. Date: Nov. 27, 2008

(54) Probe test system and method for testing a semiconductor package

(75) Inventor: Akira Matsunami, Beppu City (JP)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/805,326

(22) Filed: May 23, 2007

(51) Int. Cl. G01R 1/067; G01R 31/02

(52) U.S. Cl. 324/758; 324/754

(57) ABSTRACT

In a method and system for testing a device under test (DUT), a replaceable test connector (RTC) is disposed between a probe pin of a tester and the DUT. The RTC includes an upper test bond pad that is electrically coupled to a lower test bond pad. The probe pin is capable of being positioned to make a physical contact with the upper test bond pad, the physical contact enabling an electrical coupling there between. The lower test bond pad is capable of being positioned to make physical contact with a device bond pad of the DUT, the physical contact enabling an electrical coupling between the lower test bond pad and the device bond pad. The device bond pad is protected from potential damage from the probe pin by the RTC that is replaceable.

### BACKGROUND

The present disclosure relates generally to testing of a semiconductor device, and more particularly to a system and method for testing a semiconductor device under test (DUT) using a probe pin.

Manufacturers of electrical/electronic devices such as integrated circuits (ICs), including system-on-a-chip (SoC), radio frequency (RF) circuit devices, printed circuit boards, and other electronic circuits, typically use automatic test equipment (ATE), testers, or similar other test systems to test the devices during the production process. The test systems are generally configured to apply a test signal to the DUT and measure its response to determine a pass or fail status.

The test systems typically include a tester equipped with a probe card having one or more probe pins or needles. The probe pins are generally aligned with corresponding bond pads on a wafer to make contact and test a respective die or an IC, which is the DUT. Pressure is often exerted on the probe pins to make the physical contact, as well as the electrical contact, with the bond pad. The process of establishing an electrical contact between the tester and the DUT via the probe pin for performing the testing may likely cause damage to the bond pad surface. The damage caused by the probe pin may include gouging, scratching, scraping, or denting of the bond pad surface. A defect in a surface of the bond pad is likely to weaken the integrity of connections formed on the bond pad, e.g., due to formation of voids or cracks. Therefore, a need exists to provide a method and system for testing the DUT using a probe pin while preserving the integrity of the bond pad of the DUT.

### SUMMARY

Applicants recognize that damage caused to the surface of the bond pads by the use of probe pins is a frequently observed phenomenon in the testing of semiconductor devices. Advances in semiconductor technology are resulting in reduced bond pad sizes and a reduced pitch (or separation between the bond pads). Reduced size of bond pads often results in reduced dimensions of the probe pins. Thinner probe pins tend to reduce the contact surface with the bond pad and are likely to cause more damage to the bond pad surface. It would be desirable to conduct a test of a DUT by increasing the contact surface between the probe pin and the bond pad of the DUT while avoiding a direct contact between the probe pin and the bond pad. Accordingly, it would be desirable to provide an improved method and system for testing a DUT, absent the disadvantages found in the prior methods discussed above.

The foregoing needs are addressed by the teachings of the present disclosure, which relates to a system and method for electrically testing a DUT. According to one embodiment, in a method and system for testing a device under test (DUT), a replaceable test connector (RTC) is disposed between a probe pin of a tester and the DUT. The RTC includes an upper test bond pad that is electrically coupled to a lower test bond pad. The probe pin is capable of being positioned to make a physical contact with the upper test bond pad, the physical contact enabling an electrical coupling there between. The lower test bond pad is capable of being positioned to make physical contact with a device bond pad of the DUT, the physical contact enabling an electrical coupling between the lower test bond pad and the device bond pad. The device bond pad is protected from potential damage from the probe pin by the RTC that is replaceable.

Several advantages are achieved by the method and system according to the illustrative embodiments presented herein. The embodiments advantageously provide a method and system for protecting bond pads of a DUT from potential damage caused by the use of probe pins during testing. The embodiments advantageously provide a replaceable test connector (RTC) that is used as a replaceable or disposable connector to electrically couple the probe pins and the DUT while avoiding direct physical contact between the probe pins and the DUT. The potential damage such as gouging, scratching, scraping, or denting of contact surfaces caused by the probe pin is advantageously limited to the test bond pad surface of the RTC, which may be easily replaced. By avoiding direct contact between the probe pins and the bond pads of the DUT, the integrity of the surface of the bond pad of the DUT is advantageously preserved during the testing process. The RTC is manufacturable as a multilayer substrate, which is a well known process. The embodiments advantageously enable semiconductor device manufacturers to protect bond pads of an IC chip during testing to improve product quality and reliability.

### BRIEF DESCRIPTION OF THE DRAWINGS

FIG. 1A illustrates a block diagram of a test system for testing a device under test (DUT), according to an embodiment;

FIG. 1B illustrates a layout of a DUT described with reference to FIG. 1A, according to an embodiment;

FIG. 1C illustrates a layout of a replaceable test connector (RTC) described with reference to FIG. 1A, according to an embodiment;

FIG. 2A illustrates a simplified block diagram of a positioning system described with reference to FIG. 1A, according to an embodiment;

FIG. 2B illustrates a layout of a test marker used for alignment of a RTC described with reference to FIGS. 1A and 2A, according to an embodiment;

FIG. 2C illustrates a layout of a device marker used for alignment of a DUT described with reference to FIGS. 1A and 2A, according to an embodiment;

FIG. 3 illustrates a simplified block diagram of a damage assessment system described with reference to FIG. 1A, according to an embodiment;

FIG. 4 is a flow chart illustrating a method for testing a device under test (DUT), according to an embodiment; and

FIG. 5 is a flow chart illustrating another method for testing a device under test (DUT), according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements.

Similarly, the functionality of various mechanical elements, members, or components for forming modules, sub-assemblies and assemblies assembled in accordance with a structure for an apparatus may be implemented using various materials and coupling techniques, depending on the application requirements. Descriptive and directional terms used in the written description such as top, bottom, upper, lower, left, right, and similar others, refer to the drawings themselves as laid out on the paper and not to physical limitations of the disclosure unless specifically noted. The accompanying drawings may not to be drawn to scale and some features of embodiments shown and described herein may be simplified or exaggerated for illustrating the principles, features, and advantages of the disclosure.

Many test systems use probe pins for testing a device under test (DUT). It is well-known that when a silicon wafer is probed by probe pins during an electrical test, the probe pins may damage the surface of the bond pad, which may subsequently weaken the integrity of connections formed on the bond pad. This problem may be addressed by an intermediary connector device that avoids a physical contact between the probe pin and the DUT yet enables an electrical coupling there between.

According to one embodiment, in a method and system for testing a device under test (DUT), a replaceable test connector (RTC) is disposed between a probe pin of a tester and the DUT. The RTC includes an upper test bond pad that is electrically coupled to a lower test bond pad. The probe pin is capable of being positioned to make a physical contact with the upper test bond pad, the physical contact enabling an electrical coupling there between. The lower test bond pad is capable of being positioned to make physical contact with a device bond pad of the DUT, the physical contact enabling an electrical coupling between the lower test bond pad and the device bond pad. The device bond pad is protected from potential damage from the probe pin by the RTC that is replaceable.

The following terminology may be useful in understanding the present disclosure. It is to be understood that the terminology described herein is for the purpose of description and should not be regarded as limiting.

Electrical Connect or Interconnect—A technique to provide electrical coupling between two electrical elements. The electrical interconnect uses conductive material such as metal (e.g., aluminum, copper, silver, gold, and similar others including alloys), a conductive adhesive, a thermo compression weld, a high melting point solder contact, or a combination thereof to achieve the electrical interconnection. The interconnect, which is an essential part of any semiconductor device, may include conductive traces, conductive bumps, solder bumps, vias, metal planes, bond wires, metal lands, metal planes, bond wire areas, bond pads, metal studs, conductive pads, metal studs, and similar others. Other materials used to form the electrical connectors may include anisotropic or isotropic conductive paste. In addition, traditional mechanical connection techniques such as spring, socket, and pin, may be used to form the interconnect.

Semiconductor Package (or Package)—A semiconductor package provides the physical and electrical interface to at least one integrated circuit (IC) or die included in a semiconductor device for connecting the IC to external circuits. The package protects the IC from damage, contamination, and stress that result from factors such as handling, heating, and cooling.

Semiconductor Device—A semiconductor device is an electronic component that utilizes electronic properties of semiconductor materials to perform a desired function. A semiconductor device may be manufactured as a single discrete device or as one or more ICs packaged into a module.

Configuration—Describes a set up of an element, a circuit, a package, an electronic device, and similar other, and refers to a process for setting, defining, or selecting particular properties, parameters, or attributes of the device prior to its use or operation. Some configuration attributes may be selected to have a default value. For example, a tip of a probe pin may be configurable, e.g., to have a rounded tip or a pointed tip.

Ball grid array (BGA)—A type of chip package type that enables direct mounting of the chip to a substrate or printed circuit board via solder balls or bumps, which are mounted on corresponding bond pads. The solder balls or bumps are arranged in a grid-style array and found on the underside of the chip to make the electrical connection to the outside.

Wirebond package—Wirebonding is an electrical interconnection technique that uses thin wires and a bonding agent such as a heat, pressure and ultrasound energy or a combination thereof. The thin wires are typically bonded on corresponding bond pads of a chip. Semiconductor device packages that use wirebonding (referred to as a ‘wirebond package’) include ball grid array (single chip and multi-chip), ceramic and plastic quad flat packages, chip scale packages, and a chip on board (COB) package.

Substrate—A substrate is an underlying material used to fabricate a semiconductor device. In addition to providing base support, substrates are also used to provide electrical interconnections between the IC chip and external circuits. Two categories of substrates that are used to fabricate the semiconductor device include rigid substrates and flexible tape substrates (may also be referred to as film substrates). Rigid substrates are typically composed of a stack of thin layers or laminates, and are often referred to as multilayer laminate substrates. In some applications, the laminate substrate may include a single layer of dielectric material and a single layer of metal. Flexible tape substrates are typically composed of polymer material such as polyimide, and are often referred to as a polyimide tape substrate. The polyimide tape substrate, which typically includes at least one metal layer, is generally cheaper, thinner and more flexible compared to the multilayer laminate substrate. Interconnecting patterns such as vias provide electrical coupling between the multiple layers of the substrate. The conductive layers typically include traces of a metal foil bonded to a polymer substrate.

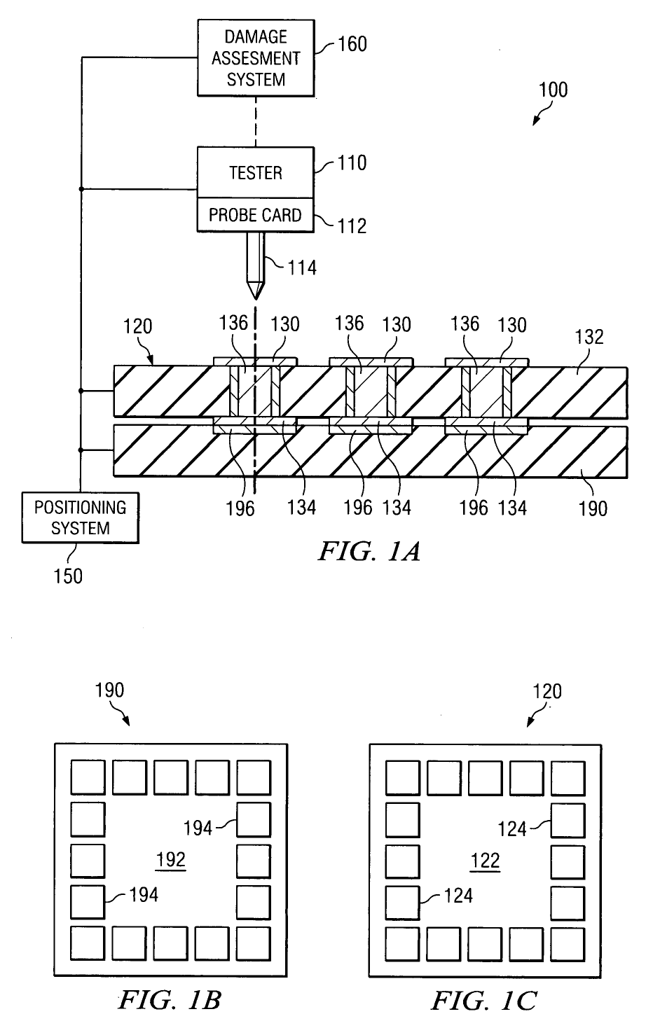

A typical semiconductor wafer contains a plurality of IC chips or dies, which are separated by saw streets. Each die may be tested prior to singulation to determine product quality, e.g., good, bad, first grade, second grade, and similar other. A test system that is used for testing each die on a wafer is described with reference to FIGS. 1A, 1B, 1C, 2A, 2B, 2C, 3, 4, and 5.

FIG. 1A illustrates a block diagram of a test system 100 for testing a device under test (DUT) 190, according to an embodiment. The test system 100 includes a tester 110 having a probe card 112 with a probe pin 114. Although not shown, it is understood that the probe card 112 may include a plurality of probe pins. In an embodiment, the DUT 190 is one of a plurality of dies contained on a silicon wafer (not shown). A replaceable test connector (RTC) 120 is disposed between the probe pin 114 and the DUT 190, thereby isolating the probe pin 114 from making a direct physical contact with the DUT 190.

FIG. 1B illustrates a top view of the DUT 190 described with reference to FIG. 1A, according to an embodiment. The DUT 190 includes an IC chip 192 that is located at the center and a plurality of device bond pads 194 that are arranged in a horizontal and vertical array located near the periphery. It is understood that the array, layout or arrangement of the plurality of device bond pads 194 may vary for each die. The plurality of device bond pads 194 may be used to couple to various electrical interconnects including solder balls and bond wires used in BGA and wirebond type packages. Any one or more of the plurality of device bond pads 194 may be selectable for performing the testing. In a particular embodiment, the plurality of device bond pads 194 is fabricated using a metal such as copper, silver, gold, nickel, zinc, platinum, cadmium, palladium, iridium, ruthenium, osmium, rhodium, iron, cobalt, indium, tin, antimony, lead, bismuth, tungsten, and alloys thereof.

FIG. 1C illustrates a top view of the RTC 120 described with reference to FIG. 1A, according to an embodiment. The RTC 120 includes a center area 122 corresponding to the location of the IC chip 192 and a plurality of upper test bond pads 124 that are arranged in a vertical and horizontal array located near the periphery. The dimensions and arrangement of the plurality of upper test bond pads 124 on the RTC 120 replicates the dimensions and arrangement of the plurality of device bond pads 194 of the DUT 190 described with reference to FIG. 1B. That is, the plurality of upper test bond pads 124 are capable of being vertically aligned with the corresponding ones of the plurality of device bond pads 194. The RTC 120 and the DUT 190 also have the same peripheral dimensions such as length and width. It is understood that the layout or the arrangement of the plurality of top test bond pads 124 may vary corresponding to each die. Any one or more of the plurality of top test bond pads 124 may be selectable for performing the testing.

In a particular embodiment, the plurality of upper test bond pads 124 are fabricated by using a metal having a higher density compared to a metal used to fabricate the plurality of device bond pads 194. The metal having the higher density is advantageously capable of withstanding a greater number of physical contacts with the probe pin 114 before being damaged compared to the metal used to form the plurality of device bond pads 194. In a particular embodiment, the metal used to form the plurality of upper test bond pads 124 may include copper, silver, gold, nickel, zinc, platinum, cadmium, palladium, iridium, ruthenium, osmium, rhodium, iron, cobalt, indium, tin, antimony, lead, bismuth, tungsten, and alloys thereof.

Referring to FIGS. 1A, 1B, and 1C, the RTC 120 is a thin, multilayer substrate, which may be fabricated as a rigid substrate or a flexible tape substrate. The RTC 120 includes an upper test bond pad 130 formed by removing a portion of a top metal layer, an insulating layer 132 disposed in the middle, and a lower test bond pad 134 formed by removing a portion of a bottom metal layer. Thus, the insulating layer 132 is disposed between the upper test bond pad 130 (which is a selected one of the plurality of upper test bond pads 124) and the lower test bond pad 134. The insulating layer 132 has a via 136 formed from a conductive material. The via 136, which is a form an electrical interconnect, electrically couples the upper test bond pad 130 and the lower test bond pad 134. In an embodiment, a thickness of the multilayer substrate may vary from about 200 micrometers to about 400 micrometers.

The test system 100 includes a positioning system 150 to properly align the contact surfaces of the probe pin 114, the RTC 120, and the DUT 190. The positioning system 150 is operable to move the RTC 120, the DUT 190, the probe pin 114, or any combination thereof to achieve the proper alignment. The probe pin 114 is capable of being positioned, e.g., by adjusting a position of the tester 110, the probe card 112, or both, to make a physical contact with the upper test bond pad 130, thereby enabling an electrical coupling between the probe pin 114 and the upper test bond pad 130.

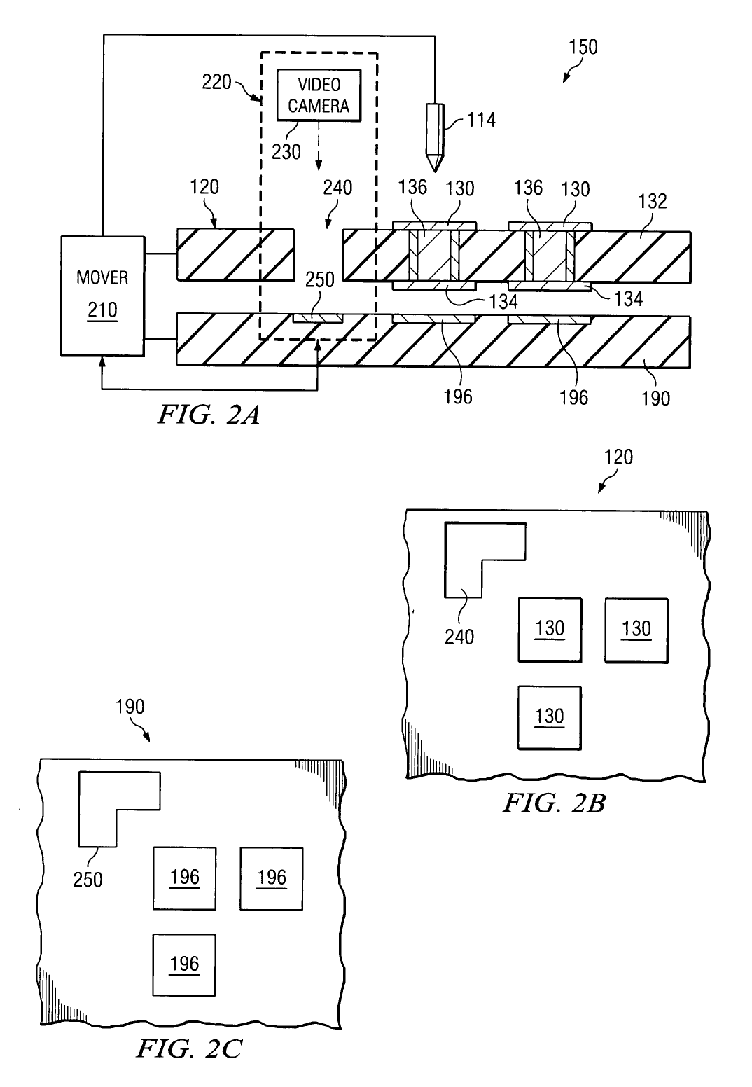

In a particular embodiment, the probe pin 114 is configured to have a rounded tip. The rounded tip advantageously provides an increased contact surface compared to a sharp pointed tip. It is understood that the particular dimensions of the tip of the probe pin 114 may depend on factors such as the surface area of the bond pad, frequency of the electrical signal provided by the tester 110 to test the DUT 190, and similar others. A slight pressure may be applied by the positioning system 150 to the probe pin 114, thereby causing the probe pin 114 to press against the surface of the upper test bond pad 130. The increased pressure may advantageously reduce the contact resistance between the probe pin 114 and the upper test bond pad 130 and between the lower test bond pad 134 and a device bond pad 196 (which is a selected one of the plurality of device bond pads 194). Additional detail of the positioning system 150 is described with reference to FIGS. 2A, 2B, and 2C.

Referring back to FIGS. 1A, 1B, and 1C, the lower test bond pad 134 is capable of being positioned by the positioning system 150 to make a physical contact with the device bond pad 196 of the DUT 190, thereby enabling an electrical coupling between the lower test bond pad 134 and the device bond pad 196. In a particular embodiment, a thickness of the bond pad such as the upper test bond pad 130, the lower test bond pad 134, and the device bond pad 196 is selectable to be between 2 micrometers and 40 micrometers.

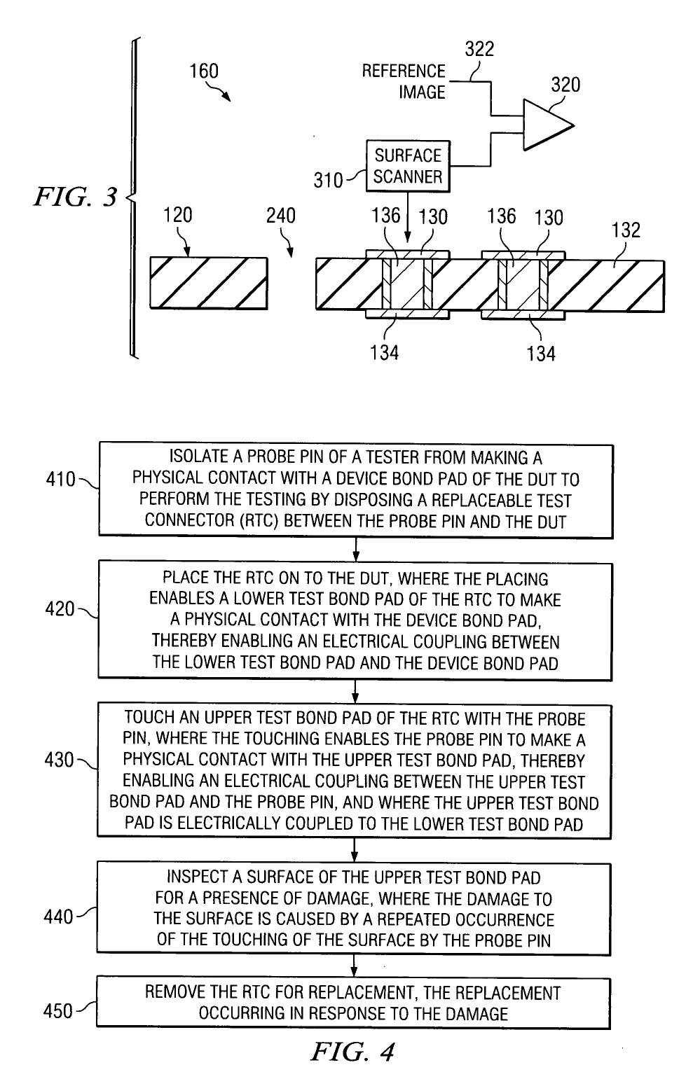

The test system 100 includes an optional damage assessment system 160 to scan the upper test bond pad 130 for potential damage and to determine whether the RTC 120 is to be replaced with a new RTC. Additional detail of the damage assessment system 160 is described with reference to FIG. 3. Referring back to FIGS. 1A, 1B, and 1C, if the damage assessment system 160 is not included, the RTC 120 may be replaceable after a configurable number of instances of the physical contact occurring between the upper test bond pad 130 and the probe pin 114.

In an exemplary, non-depicted embodiment, an RTC may be sized to fit a wafer instead of the RTC 120 that is sized for a single die. In this embodiment, the wafer is the DUT. The wafer sized RTC may reduce test time since any one of the dies on the wafer may be tested without having to reposition and realign the RTC. In an exemplary, non-depicted embodiment, the DUT 190 is at least one of a microprocessor, an application specific integrated circuit (ASIC), a digital signal processor, a radio frequency chip, a memory, a microcontroller, and a system-on-a-chip, or a combination thereof.

FIG. 2A illustrates a simplified block diagram of the positioning system 150 described with reference to FIG. 1A, according to an embodiment. FIG. 2B illustrates a top view of a test marker used for an alignment of the RTC 120, according to an embodiment. FIG. 2C illustrates a top view of a device marker used for an alignment of the DUT 190, according to an embodiment. As described earlier with reference to FIGS. 1A, 1B, and 1C, the positioning system 150 is operable to properly align the contact surfaces of the probe pin 114, the RTC 120, and the DUT 190. A proper alignment enables the probe pin 114, the upper test bond pad 130, the lower test bond pad 134, and the device bond pad 196 to have a common vertical axis. The proper alignment also enables electrical coupling between the tester 110 and the DUT 190 via the RTC 120.

Referring to FIGS. 2A, 2B, and 2C, the positioning system 150 includes a mover 210 and an alignment system 220. The mover 210, e.g., a servo motor, is operable to move the RTC 120, the DUT 190, the probe pin 114, or any combination thereof to achieve the proper alignment. The alignment system 220 includes a video camera 230 that is focused on a test marker 240, which is in the form of an opening or a slit, located on the RTC 120 and a matching device marker 250 located on the DUT 190. The mover 210 is capable of being positioned in response to the alignment of the test marker 240 and the device marker 250 as viewed by the video camera 230. That is, the test marker 240 and the device marker 250 are used to advantageously align the RTC 120 with the DUT 190. Once properly aligned, the position of the RTC 120 and the DUT 190 may be secured to avoid undesirable motion and misalignment during the testing.

In an exemplary, non-depicted embodiment, if an RTC is sized to fit a wafer (instead of the RTC 120 that is sized for a single die on the wafer), the device marker 250 may be placed on a wafer and the test marker 240 may be placed on the RTC sized to fit the wafer. It is understood that the shape and size of the test marker 240 and the matching device marker 250 may vary depending on each application.

In a particular embodiment, proper alignment may be achieved without the use of the alignment markers. That is, the video camera 230 may be used to properly align the peripheral edges of the RTC 120 and the DUT 190. Since the layout and peripheral dimensions of the bond pads on the RTC 120 is identical to that of the DUT 190, a proper alignment occurs by aligning the peripheral edges.

FIG. 3 illustrates a simplified block diagram of the optional damage assessment system 160 described with reference to FIG. 1A, according to an embodiment. The damage assessment system 160 includes a surface scanner 310 operable to scan a surface of the upper test bond pad 130 for damage and a comparator 320 to determine a presence of the damage. In a particular embodiment, the surface scanner 310 may be the video camera 230 described with reference to FIGS. 2A, 2B, and 2C. The surface scanner 310 stores an image of the surface. The image contains information about the defects or damage present on the surface. As described earlier, the damage to the surface may be caused by repeated physical contacts between the tip of the probe pin 114 and the surface of the upper test bond pad 130. The comparator 320 compares the image to a reference image 322, e.g., image of a surface of a new bond pad. If the deviation is greater than a threshold than the RTC 120 is damaged and is to be replaced by a new RTC. As described earlier, the optional damage assessment system 160 may be bypassed by automatically replacing the RTC 120 with a new RTC based on a number of instances of a physical contact between the probe pin 114 and the upper test bond pad 130.

FIG. 4 is a flow chart illustrating a method for testing a device under test (DUT), according to an embodiment. In a particular embodiment, the method is used to test the DUT 190 described with reference to FIGS. 1A, 1B, 1C, 2A, 2B, 2C, and 3. At step 410, a probe pin of a tester is isolated from making a physical contact with a device bond pad of the DUT to perform the testing by disposing a replaceable test connector (RTC) between the probe pin and the DUT. At step 420, the RTC is placed on to the DUT. The placing enables a lower test bond pad of the RTC to make a physical contact with the device bond pad, thereby enabling an electrical coupling between the lower test bond pad and the device bond pad. At step 430, an upper test bond pad of the RTC is touched by the probe pin. The touching enables the probe pin to make a physical contact with the upper test bond pad, thereby enabling an electrical coupling between the upper test bond pad and the probe pin. The upper test bond pad is electrically coupled to the lower test bond pad.

Various steps described above may be added, omitted, combined, altered, or performed in different orders. For example, steps 440 and 450 may be added after the step 430. At step 440, a surface of the upper test bond pad is inspected for a presence of damage, the damage to the surface being caused by a repeated occurrence of the touching of the surface by the probe pin. At step 450, the RTC is removed for replacement if the surface is damaged.

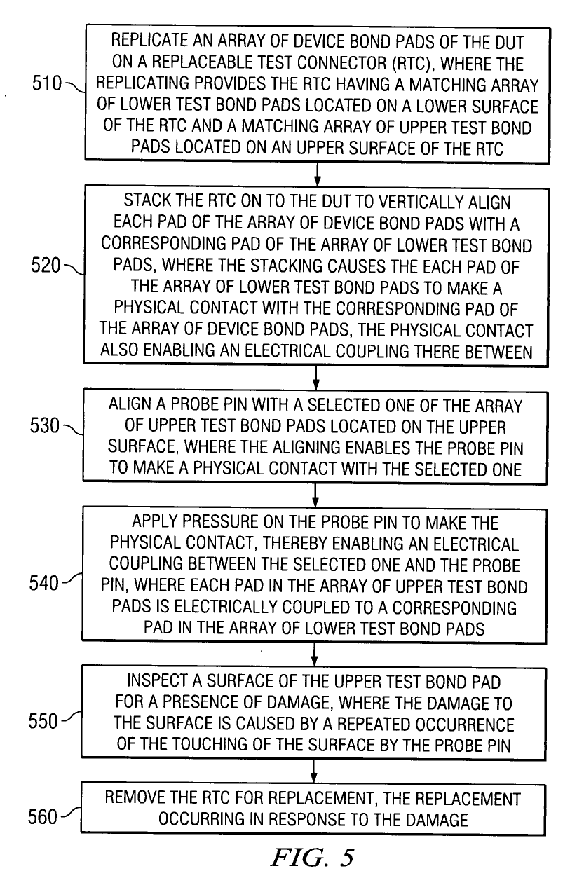

FIG. 5 is a flow chart illustrating another method for testing a device under test (DUT), according to an embodiment. In a particular embodiment, the method is used to test the DUT 190 described with reference to FIGS. 1A, 1B, 1C, 2A, 2B, 2C, and 3. At step 510, an array of device bond pads of the DUT is replicated on a replaceable test connector (RTC). The replication provides the RTC having a matching array of lower test bond pads located on a lower surface of the RTC and a matching array of upper test bond pads located on an upper surface of the RTC. At step 520, the RTC is stacked on to the DUT to vertically align each pad of the array of device bond pads with a corresponding pad of the array of lower test bond pads. The stacking causes the each pad of the array of lower test bond pads to make a physical contact with the corresponding pad of the array of device bond pads, the physical contact also enabling an electrical coupling there between. At step 530, a probe pin is aligned with a selected one of the array of upper test bond pads located on the upper surface. The aligning enables the probe pin to make a physical contact with the selected one. At step 540, pressure is applied on the probe pin to make the physical contact, thereby enabling an electrical coupling between the selected one and the probe pin. Each pad in the array of upper test bond pads is electrically coupled to a corresponding pad in the array of lower test bond pads.

Various steps described above may be added, omitted, combined, altered, or performed in different orders. For example, steps 550 and 560 may be added after the step 540. At step 550, a surface of the selected one is inspected for a presence of damage, the damage to the surface being caused by a repeated occurrence of the touching of the surface by the probe pin. At step 560, the RTC is removed for replacement if the surface is damaged.

Several advantages are achieved by the method and system according to the illustrative embodiments presented herein. The embodiments advantageously provide for protecting bond pads of a DUT from potential damage caused by the use of probe pins during testing. The embodiments advantageously provide a replaceable test connector (RTC) that is used as a replaceable or disposable connector to electrically couple the probe pins and the DUT while avoiding direct physical contact between the probe pins and the DUT. The potential damage such as gouging, scratching, scraping, or denting of contact surfaces caused by the probe pin is advantageously limited to the test bond pad surface of the RTC, which may be easily replaced. By avoiding direct contact between the probe pins and the bond pads of the DUT, the integrity of the surface of the bond pad of the DUT is advantageously preserved during the testing process. The RTC is manufacturable as a multilayer substrate, which is a well known process. The embodiments advantageously enable semiconductor device manufacturers to protect bond pads of an IC chip during testing to improve product quality and reliability.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of using a removable test connector (RTC) that is sized to fit a die on a wafer, those of ordinary skill in the art will appreciate that the processes disclosed herein are capable of testing all dies contained on the wafer by having a wafer sized RTC.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

1. A test system comprising:
a tester having a probe pin;
a replaceable test connector (RTC) having an upper test bond pad that is electrically coupled to a lower test bond pad, wherein the probe pin is capable of being positioned to make a physical contact with the upper test bond pad, thereby enabling an electrical coupling between the probe pin and the upper test bond pad; and
a device under test (DUT) having a device bond pad, wherein the lower test bond pad is capable of being positioned to make a physical contact with the device bond pad, thereby enabling an electrical coupling between the lower test bond pad and the device bond pad.

2. The test system of claim 1 further comprising:
a positioning system including:
a mover to enable a movement of the RTC, the DUT, the probe pin, or a combination thereof, wherein the movement is adjustable to enable the electrical coupling between the probe pin and the RTC and between the RTC and the DUT; and
an alignment system including:
a test marker located on the RTC;
a device marker located on the DUT, wherein the movement is adjusted corresponding to a difference in alignment between the test marker and the device marker.

3. The test system of claim 1 further comprising:
a damage assessment system including:
a surface scanner to scan a surface of the upper test bond pad for damage; and
a comparator to determine a presence of the damage.

4. The test system of claim 3, wherein the RTC is replaced with a new RTC in response to the presence of the damage.

5. The test system of claim 1, wherein the RTC is disposed between the probe pin and the DUT, thereby isolating the probe pin from making a physical contact with the device bond pad of the DUT.

6. The test system of claim 1, wherein the RTC is a multilayer substrate, wherein the multilayer substrate includes:
an upper metal layer used to form the upper test bond pad;
a lower metal layer used to form the lower test bond pad; and
an insulating layer disposed between the lower metal layer and the upper metal layer, wherein the insulating layer has a via formed from a conductive material, wherein the via electrically couples the upper test bond pad and the lower test bond pad.

7. The test system of claim 1, wherein a thickness of the upper test bond pad and a thickness of the lower test bond pad is between 2 micrometers and 40 micrometers.

8. The test system of claim 1, wherein the upper test bond pad is fabricated from a metal having a higher density compared to another metal used to fabricate the device bond pad, wherein the metal having the higher density is capable of withstanding a greater number of physical contacts with the probe pin before being damaged compared to the another metal.

9. The test system of claim 1, wherein a tip of the probe pin is rounded.

10. The test system of claim 1, wherein the DUT is at least one of a microprocessor, an application specific integrated circuit (ASIC), a digital signal processor, a radio frequency chip, a memory, a microcontroller, and a system-on-a-chip, or a combination thereof.

11. The test system of claim 1, wherein a size and location of the lower test bond pad on the RTC is identical to a size and location of the device bond pad on the DUT, wherein a size and location of the upper test bond pad on the RTC is identical to the size and location of the lower test bond pad on the RTC.

12. The test system of claim 1, wherein the RTC is replaceable after a configurable number of instances of the physical contact occurring between the upper test bond pad and the probe pin.

13. A method for testing a device under test (DUT), the method comprising:
isolating a probe pin of a tester from making a physical contact with a device bond pad of the DUT to perform the testing by disposing a replaceable test connector (RTC) between the probe pin and the DUT;
placing the RTC on to the DUT, wherein the placing enables a lower test bond pad of the RTC to make a physical contact with the device bond pad, thereby enabling an electrical coupling between the lower test bond pad and the device bond pad; and
touching an upper test bond pad of the RTC with the probe pin, wherein the touching enables the probe pin to make a physical contact with the upper test bond pad, thereby enabling an electrical coupling between the upper test bond pad and the probe pin, wherein the upper test bond pad is electrically coupled to the lower test bond pad.

14. The method of claim 13 further comprising:
inspecting a surface of the upper test bond pad for a presence of damage, wherein the damage to the surface is caused by a repeated occurrence of the touching of the surface by the probe pin; and
removing the RTC for replacement, the replacement occurring in response to the damage.

15. The method of claim 13, wherein the placing includes:
aligning a device marker of the DUT with a test marker of the RTC, thereby positioning the lower test bond pad vertically above the device bond pad; and
moving at least one of the RTC and the DUT towards one another to make the physical contact there between.

16. The method of claim 13, wherein the touching includes applying pressure on the probe pin to lower a resistance of an electrical contact between the probe pin and the upper test bond pad, and another electrical contact between lower test bond pad and the device bond pad.

17. The method of claim 13, wherein the DUT is at least one of a microprocessor, an application specific integrated circuit (ASIC), a digital signal processor, a radio frequency chip, a memory, a microcontroller, and a system-on-a-chip, or a combination thereof.

18. The method of claim 13, wherein the RTC is replaceable after a configurable number of instances of the physical contact occurring between the upper test bond pad and the probe pin.

19. The method of claim 13, wherein RTC is a tape substrate.

20. A method for testing a device under test (DUT), the method comprising:
replicating an array of device bond pads of the DUT on a replaceable test connector (RTC), wherein the replicating provides the RTC having a matching array of lower test bond pads located on a lower surface of the RTC and a matching array of upper test bond pads located on an upper surface of the RTC;
stacking the RTC on to the DUT to vertically align each pad of the array of device bond pads with a corresponding pad of the array of lower test bond pads, wherein the stacking causes the each pad of the array of lower test bond pads to make a physical contact with the corresponding pad of the array of device bond pads, the physical contact also enabling an electrical coupling there between;
aligning a probe pin with a selected one of the array of upper test bond pads located on the upper surface, wherein the aligning enables the probe pin to make a physical contact with the selected one; and
applying pressure on the probe pin to make the physical contact, thereby enabling an electrical coupling between the selected one and the probe pin, wherein each pad in the array of upper test bond pads is electrically coupled to a corresponding pad in the array of lower test bond pads.

21. The test system of claim 1, wherein the RTC is coupled to the DUT in a replaceable manner.

22. The test system of claim 1, wherein the RTC is sized to fit a single die.
